(19) United States
(12) Patent Application Publication
(10) Pub. No.: US 2025/0072141 A1
(43) Pub. Date: Feb. 27, 2025

(54) IMAGING DEVICE

(71) Applicant: SONY SEMICONDUCTOR SOLUTIONS CORPORATION, KANAGAWA (JP)

(72) Inventor: JUNJI NARUSE, KANAGAWA (JP)

(21) Appl. No.: 18/726,617

(22) PCT Filed: Dec. 6, 2022
(86) PCT No.: PCT/JP2022/044994

§ 371 Date: Jul. 3, 2024

(30) Foreign Application Priority Data
Jan. 13, 2022 (JP) 2022-003707

(51) Int. Cl. H01L 27/146

(52) U.S. Cl. CPC H01L 27/14621; H01L 27/14605; H01L 27/14627

(57) ABSTRACT

Provided is an imaging device enabling to impart wavelength selectivity to a light condensing effect and improve spectral characteristics. An imaging device includes: a semiconductor layer in which a plurality of pixels is arranged; a color filter provided on one surface side of the semiconductor layer; and a flat lens having a flat light incident surface and provided on the one surface side of the semiconductor layer with the color filter interposed in between. The color filter includes a first filter component that transmits light of a first color and a second filter component that transmits light of a second color different from the first color. The flat lens includes a first lens portion facing the first filter component, and a second lens portion facing the second filter component. The first lens portion and the second lens portion have mutually different thicknesses.

### TECHNICAL FIELD

The present disclosure relates to an imaging device.

### BACKGROUND ART

There is known an imaging device that condenses incident light on a light reception unit formed on a substrate by using an on-chip microlens having a rectangular cross section (see, for example, Patent Document 1).

### CITATION LIST

### Patent Document

Patent Document 1: Japanese Patent Application Laid-Open No. 2010-239077

### SUMMARY OF THE INVENTION

### Problems to be Solved by the Invention

The rectangular on-chip lens has a structure of condensing light by using a phase difference of light. However, all the rectangular on-chip lenses using a phase difference of light have the same shape, and there has been no wavelength selectivity in a light condensing effect similarly to the conventional hemispherical on-chip lenses.

The present disclosure has been made in view of such circumstances, and an object of the present disclosure is to provide an imaging device enabling to impart wavelength selectivity to a light condensing effect and improve spectral characteristics.

### Solutions to Problems

An imaging device according to one aspect of the present disclosure includes: a semiconductor layer in which a plurality of pixels is arranged; a color filter provided on one surface side of the semiconductor layer; and a flat lens having a flat light incident surface and provided on the one surface side of the semiconductor layer with the color filter interposed in between. A thickness of the flat lens is mutually different between adjacent pixels.

According to this configuration, light in one wavelength region can be condensed to one adjacent pixel, and light in other wavelength regions can be made difficult to be condensed. Light in another wavelength region can be condensed to another adjacent pixel, and light in other wavelength regions can be made difficult to be condensed. Regarding a light condensing effect on pixels by the flat lens, wavelength selectivity can be imparted to each of one pixel and another pixel, so that spectral characteristics can be improved.

An imaging device according to another aspect of the present disclosure includes: a semiconductor layer in which a plurality of pixels is arranged; a color filter provided on one surface side of the semiconductor layer; and a flat lens having a flat light incident surface and provided on the one surface side of the semiconductor layer with the color filter interposed in between. The color filter includes a first filter component that transmits light of a first color and a second filter component that transmits light of a second color different from the first color. The flat lens includes a first lens portion facing the first filter component, and a second lens portion facing the second filter component. The first lens portion and the second lens portion have mutually different thicknesses.

According to this configuration, the thickness of the first lens portion can be designed such that diffraction efficiency of light of the first color is maximized. As a result, light of the first color can be condensed on the pixels (hereinafter, also referred to as pixels for first color detection) facing each other with the first lens portion and the first filter component interposed in between, and other light can be made difficult to be condensed. Similarly, the thickness of the second lens portion can be designed such that diffraction efficiency of light of the second color is maximized. As a result, light of the second color can be condensed on the pixels (hereinafter, also referred to as pixels for second color detection) facing each other with the second lens portion and the second filter component interposed in between, and other light can be made difficult to be condensed. Regarding a light condensing effect on pixels by the flat lens, wavelength selectivity can be imparted to each pixel for first color detection and each pixel for second color detection, so that spectral characteristics can be improved.

### BRIEF DESCRIPTION OF DRAWINGS

FIG. 1 is a diagram illustrating an overall configuration example of an imaging device according to a first embodiment of the present disclosure.

FIG. 2 is a plan view illustrating a configuration example of a color filter and a flat lens of the imaging device according to the first embodiment of the present disclosure.

FIG. 3 is a cross-sectional view illustrating a configuration example of the imaging device according to the first embodiment of the present disclosure.

FIG. 4 is a cross-sectional view illustrating wavelength selectivity of a light condensing effect by the flat lens in the imaging device according to the first embodiment of the present disclosure.

FIG. 5A is a cross-sectional view illustrating a manufacturing method for the flat lens according to the first embodiment of the present disclosure in order of processes.

FIG. 5B is a cross-sectional view illustrating the manufacturing method for the flat lens according to the first embodiment of the present disclosure in order of processes.

FIG. 5C is a cross-sectional view illustrating the manufacturing method for the flat lens according to the first embodiment of the present disclosure in order of processes.

FIG. 5D is a cross-sectional view illustrating the manufacturing method for the flat lens according to the first embodiment of the present disclosure in order of processes.

FIG. 5E is a cross-sectional view illustrating the manufacturing method for the flat lens according to the first embodiment of the present disclosure in order of processes.

FIG. 5F is a cross-sectional view illustrating the manufacturing method for the flat lens according to the first embodiment of the present disclosure in order of processes.

FIG. 6 is a cross-sectional view illustrating a configuration example of an imaging device according to a second embodiment of the present disclosure.

FIG. 7 is a cross-sectional view illustrating wavelength selectivity of a light condensing effect by a flat lens in the imaging device according to the second embodiment of the present disclosure.

FIG. 8 is a cross-sectional view illustrating a configuration example of an imaging device according to a third embodiment of the present disclosure.

FIG. 9 is a cross-sectional view illustrating a configuration example of an imaging device according to a fourth embodiment of the present disclosure.

FIG. 10 is a plan view illustrating a configuration example of a color filter and a flat lens of an imaging device according to a fifth embodiment of the present disclosure.

FIG. 11 is a cross-sectional view illustrating a configuration example of an imaging device according to a sixth embodiment of the present disclosure.

### MODE FOR CARRYING OUT THE INVENTION

Hereinafter, embodiments of the present disclosure will be described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it goes without saying that dimensional relationships and ratios are partly different between the drawings.

Definition of directions such as upward and downward directions in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

In the following description, there is a case where the direction is described using terms such as an X-axis direction, a Y-axis direction, and a Z-axis direction. For example, the X-axis direction and the Y-axis direction are directions parallel to a back surface 111b of a substrate 111. The X-axis direction and the Y-axis direction are also referred to as horizontal directions. The Z-axis direction is a normal direction of the back surface 111b of the substrate 111. The X-axis direction, the Y-axis direction, and the Z-axis direction are orthogonal to each other.

### First Embodiment

### Overall Configuration

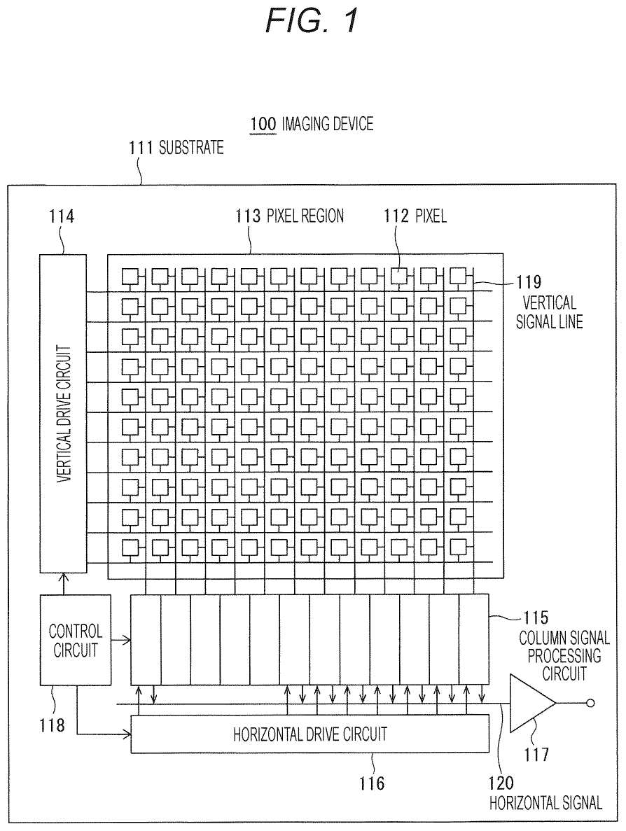

FIG. 1 is a diagram illustrating an overall configuration example of an imaging device 100 according to a first embodiment of the present disclosure. The imaging device 100 illustrated in FIG. 1 includes the substrate 111 containing silicon, a pixel region (so-called imaging region) 113 having a plurality of pixels 112 arranged on the substrate 111, and a peripheral circuit unit. The peripheral circuit unit includes a vertical drive circuit 114, a column signal processing circuit 115, a horizontal drive circuit 116, an output circuit 117, and a control circuit 118.

The pixel region 113 includes a plurality of pixels 112 regularly arranged in a two-dimensional array. The pixel region 113 includes: a pixel unit configured to receive incident light, amplify a signal charge generated by photoelectric conversion, and read the signal charge to the column signal processing circuit 115; and an optical black unit (hereinafter, an OPB unit) for output of optical black serving as a reference of a black level. The OPB unit is provided in a region adjacent to the pixel unit, such as an outer peripheral portion of the pixel unit.

The pixel 112 includes, for example, a photoelectric conversion element (not illustrated) that is a photodiode, and a plurality of pixel transistors (so called MOS transistors). The plurality of pixels 112 is regularly arranged in a two-dimensional array on the substrate 111. The plurality of pixel transistors may include three transistors of a transfer transistor, a reset transistor, and an amplification transistor. The plurality of pixel transistors may include four transistors by adding a selection transistor to the above-described three transistors. The pixel 112 may have a shared pixel structure. The shared pixel structure includes a plurality of photodiodes, a plurality of transfer transistors, one shared floating diffusion, and other shared pixel transistors one for each type.

The control circuit 118 generates a clock signal and a control signal serving as references for operations of the vertical drive circuit 114, the column signal processing circuit 115, and the horizontal drive circuit 116 on the basis of a vertical synchronization signal, a horizontal synchronization signal, and a master clock signal. The control circuit 118 controls the vertical drive circuit 114, the column signal processing circuit 115, and the horizontal drive circuit 116 using the clock signal and the control signal.

The vertical drive circuit 114 including a shift register, for example, selectively scans the pixels 112 sequentially in a vertical direction row by row. The vertical drive circuit 114 supplies a pixel signal based on a signal charge generated depending on a received amount of light in the photoelectric conversion element of the pixel 112 to the column signal processing circuit 115 through a vertical signal line 119.

The column signal processing circuit 115 is arranged for each column of the pixels 112, for example. The column signal processing circuit 115 performs signal processing such as noise removal and signal amplification on signals output from the pixels 112 of one row for each pixel column, with a signal from the OPB unit. In an output stage of the column signal processing circuit 115, a horizontal selection switch not illustrated is connected between the same and a horizontal signal line 120.

The horizontal drive circuit 116 includes a shift register, for example. The horizontal drive circuit 116 selects each of the column signal processing circuits 115 in turn by sequentially outputting horizontal scanning pulses, and causes each of the column signal processing circuits 115 to output the pixel signal to the horizontal signal line 120.

The output circuit 117 performs signal processing on the pixel signals sequentially supplied from each of the column signal processing circuits 115 via the horizontal signal line 120, and outputs the same to an external device not illustrated.

The output circuit 117 performs signal processing on signals sequentially supplied from each of the column signal processing circuits 115 through the horizontal signal line 120 and outputs processed signals. For example, there is a case where the output circuit 117 performs only buffering and a case where this performs black level adjustment, column variation correction, various types of digital signal processing and the like.

### Configuration Example of Pixel Region

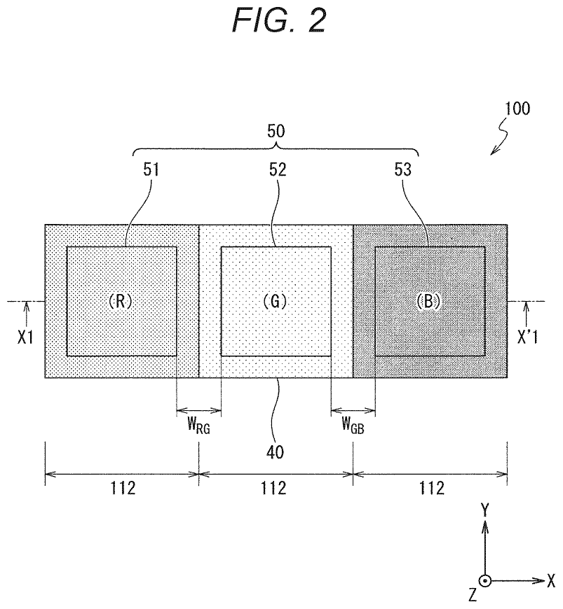

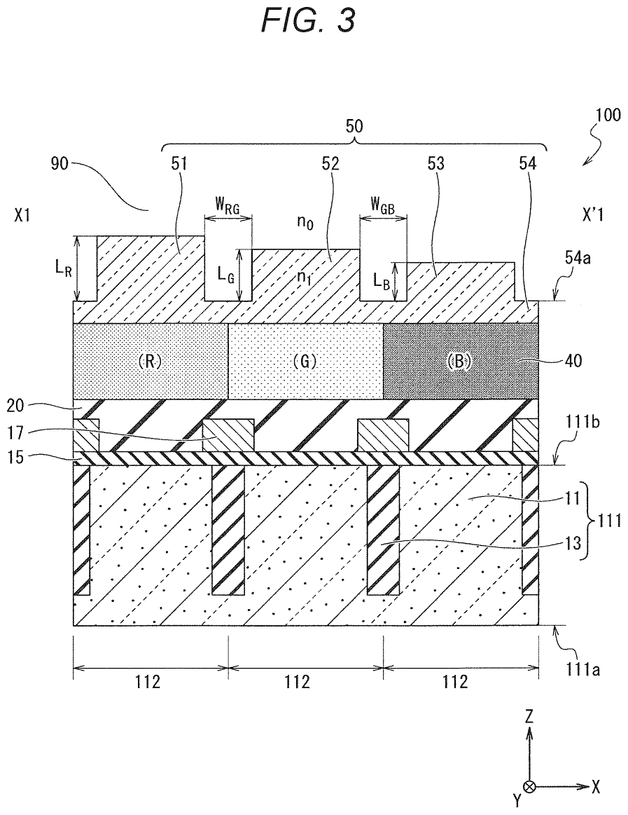

Next, details of the imaging device 100 will be described with reference to FIGS. 2 and 3. FIG. 2 is a plan view illustrating a configuration example of a color filter 40 and a flat lens 50 of the imaging device 100 according to the first embodiment of the present disclosure. FIG. 3 is a cross-sectional view illustrating a configuration example of the imaging device 100 according to the first embodiment of the present disclosure. A cross section of the plan view illustrated in FIG. 2 taken along line X1-X′1 corresponds to the cross-sectional view illustrated in FIG. 3.

The imaging device 100 illustrated in FIGS. 2 and 3 is, for example, a back-illuminated solid-state imaging device, and includes: the substrate 111 (an example of a “semiconductor layer” of the present disclosure); insulating films 15 and 20 provided on the back surface 111b (an example of “one surface” of the present disclosure, an upper surface in FIG. 2) side of the substrate 111; a light shielding film 17; the color filter 40; and the flat lens 50 having a flat light incident surface (in FIG. 3, an upper surface). Furthermore, although not illustrated, the imaging device 100 includes an interlayer insulating film provided on a front surface 111a (in FIG. 2, a lower surface) side of the substrate 111, a wiring layer arranged inside the interlayer insulating film, and the like.

The substrate 111 contains, for example, silicon. The substrate 111 is provided with the plurality of pixels 112 in a two-dimensional matrix (see FIG. 1). Each of the plurality of pixels 112 includes a photoelectric conversion element 11 provided on the substrate 111 and a plurality of pixel transistors arranged on the front surface 111a side of the substrate 111. The photoelectric conversion element 11 is, for example, a photodiode, and a signal charge corresponding to an amount of received incident light is generated and accumulated.

Furthermore, the substrate 111 is provided with an element isolation layer 13 that electrically isolates adjacent pixels 112 from each other. For example, the element isolation layer 13 includes a high-concentration impurity layer provided on the substrate 111, a silicon oxide film embedded in a trench provided on the substrate 111, or the like. The element isolation layer 13 may be formed, for example, from the back surface 111b of the substrate 111 to an intermediate position (that is, an intermediate position in a depth direction of the substrate 111) between the back surface 111b and the front surface 111a, or may be formed so as to penetrate the substrate 111 from the back surface 111b to the front surface 111a of the substrate 111.

The insulating film 15 is provided on the back surface 111b (in FIG. 2, the upper surface) of the substrate 111. The insulating film 15 is a protective film for protection of the back surface 111b of the substrate 111. The insulating film 15 includes, for example, a silicon oxide film.

The light shielding film 17 is provided on the insulating film 15. The light shielding film 17 is arranged at a boundary between one pixel 112 and another pixel 112 adjacent to each other. The light shielding film 17 contains any metal material that shields visible light, such as tungsten (W) or copper (Cu), for example. The light shielding film 17 can reflect, toward the one filter component side, light that is about to enter from one filter component (for example, a red filter component (R) to be described later) included in the color filter 40 to another filter component (for example, a green filter component (G) to be described later) adjacent to the one filter component.

The insulating film 20 is provided on the insulating film 15 and covers the light shielding film 17. The insulating film 20 functions as a protective film that prevents the color filter 40 and the substrate 111 from coming into direct contact with each other. Furthermore, the insulating film 20 also functions as a protective film for protection of the back surface 111b of the substrate 111 and the light shielding film 17 from an etching atmosphere or the like when the color filter 40 or the like is formed. The insulating film 20 includes, for example, a silicon oxide film.

The color filter 40 is provided on the back surface 111b side of the substrate 111 with the insulating film 20 interposed in between. The color filter 40 has a plurality of filter components, and includes, for example, a red filter component (R) that transmits red light, a green filter component (G) that transmits green light, and a blue filter component (B) that transmits blue light.

Red is an example of a “first color” of the present disclosure, and the red filter component (R) is an example of a “first filter component” of the present disclosure. Green is an example of a “second color” of the present disclosure, and the green filter component (G) is an example of a “second filter component” of the present disclosure. Blue is an example of a “third color” of the present disclosure, and the green filter component (G) is an example of a “third filter component” of the present disclosure.

Note that, although FIGS. 2 and 3 illustrate a mode in which the red filter component (R), the green filter component (G), and the blue filter component (B) are aligned in this order along the X-axis direction, this is merely an example. In each embodiment of the present disclosure, the alignment order of the red filter component (R), the green filter component (G), and the blue filter component (B) is not particularly limited. The red filter component (R), the green filter component (G), and the blue filter component (B) may have any arrangement. The blue filter component (B) and the red filter component (R) may be adjacent to each other. Furthermore, the first color, the second color, and the third color of the present disclosure are not limited to those described above, and may be any color (wavelength range).

The flat lens 50 is provided on the color filter 40. The flat lens 50 is a lens array in which a light incident surface (in FIG. 3, the upper surface) is not a concave surface or a convex surface but a flat surface (for example, a horizontal plane parallel to the X-axis direction and the Y-axis direction). The flat lens 50 contains, for example, a translucent organic material or a translucent inorganic material through which visible light can pass. The light incident from the back surface 111b side of the substrate 111 is condensed by the flat lens 50 and enters the color filter 40. In the color filter 40, light having a desired wavelength is transmitted, and the transmitted light enters the photoelectric conversion element 11 in the substrate 111.

### Configuration Example of Flat Lens

As illustrated in FIGS. 2 and 3, the flat lens 50 includes, for example, a first lens portion 51 facing the red filter component (R) of the color filter 40, a second lens portion 52 facing the green filter component (G) of the color filter 40, a third lens portion 53 facing the blue filter component (B) of the color filter 40, and a base part 54. The first lens portion 51, the second lens portion 52, and the third lens portion 53 are provided so as to protrude from an upper surface 54a of the base part 54. The first lens portion 51, the second lens portion 52, the third lens portion 53, and the base part 54 are integrally formed.

As illustrated in FIG. 3, shapes of the first lens portion 51, the second lens portion 52, and the third lens portion 53 in a cross-sectional view are, for example, rectangular. That is, for each of the first lens portion 51, the second lens portion 52, and the third lens portion 53, a cross-sectional shape taken along a plane orthogonal to an incident surface (in FIG. 3, the upper surface) on which light enters is rectangular. Furthermore, as illustrated in FIG. 2, shapes of the first lens portion 51, the second lens portion 52, and the third lens portion 53 in plan view are also rectangular, for example.

In FIG. 3, a height from the upper surface 54a of the base part 54 to an upper surface of the first lens portion 51 corresponds to a thickness L_{R} of the first lens portion 51. A height from the upper surface 54a of the base part 54 to the upper surface of the first lens portion 51 corresponds to a thickness L_{G} of the second lens portion 52. A height from the upper surface 54a of the base part 54 to an upper surface of the third lens portion 53 corresponds to a thickness L_{B} of the third lens portion 53. The thickness L_{R} of the first lens portion 51 is expressed by the following Equation (1). The thickness L_{G} of the second lens portion 52 is expressed by the following Equation (2). The thickness L_{B} of the third lens portion 53 is expressed by the following Equation (3).

$$[ Mathematical Equation 1 ]$$

$${L}_{R} = ( a + 1 / 2 ) \frac{{λ}_{R}}{( {n}_{1} - {n}_{0} )} \qquad ( 1 )$$

$${L}_{G} = ( b + 1 / 2 ) \frac{{λ}_{G}}{( {n}_{1} - {n}_{0} )} \qquad ( 2 )$$

$${L}_{B} = ( c + 1 / 2 ) \frac{{λ}_{B}}{( {n}_{1} - {n}_{0} )} \qquad ( 3 )$$

In Equations (1) to (3) described above and Equations (4) to (6) described later, λ_{R} is a target wavelength of light to be condensed on the red filter component (R) of the color filter 40, λ_{G} is a target wavelength of light to be condensed on the green filter component (G) of the color filter 40, and λ_{B} is a target wavelength of light to be condensed on the blue filter component (B) of the color filter 40. In one example, λ_{R} is 400 nm or more and 480 nm or less (that is, red light), λ_{G} is 500 nm or more and 580 nm or less (that is, green light), and λ_{B} is 580 nm or more and 650 nm or less (that is, blue light).

Furthermore, no is a refractive index of a medium layer located on a side (in FIG. 3, the upper surface side of the flat lens 50) opposite to the color filter 40 with the flat lens 50 interposed in between. In the example illustrated in FIG. 3, the medium layer is air, and the refractive index n₀ of the medium layer is 1. n₁ is a refractive index of a material contained in the flat lens 50. The refractive index n1 of the flat lens 50 is a value higher than the refractive index n₀ of the medium layer, and (n₁−n₀) is a value larger than 0. For example, (n₁−n₀) is set to 0.3 or more and 1.1 or less. Furthermore, each value of a, b, and c is an integer of 0 or more (that is, zero or a positive integer). a, b, and c may have the same value or mutually different values.

When calculated from Equation (1), the thickness L_{R} of the first lens portion 51 is ((a+½)×363) nm or more and ((a+½)×1600) nm or less. The thickness L_{R} of the first lens portion 51 is 181 nm or more and 800 nm or less when a=0, and is 544 nm or more and 2400 nm or less when a=1. Note that, in the calculation described above, a fraction of a lower limit value has been rounded down, and a fraction of the upper limit value has been rounded up.

Similarly, when calculated from Equation (2), the thickness L_{G} of the second lens portion 52 is ((b+½)×454) nm or more and ((b+½)×1934) nm or less. The thickness L_{G} of the second lens portion 52 is 227 nm or more and 967 nm or less when b=0, and is 681 nm or more and 2901 nm or less when b=1.

When calculated from Equation (3), the thickness L_{B} of the third lens portion 53 is ((c+½)×527) nm or more and ((c+½)×2167) nm or less. The thickness L_{B} of the third lens portion 53 is 263 nm or more and 1084 nm or less when c=0, and is 790 nm or more and 3251 nm or less when c=1.

### Wavelength Selectivity of Light Condensing Effect

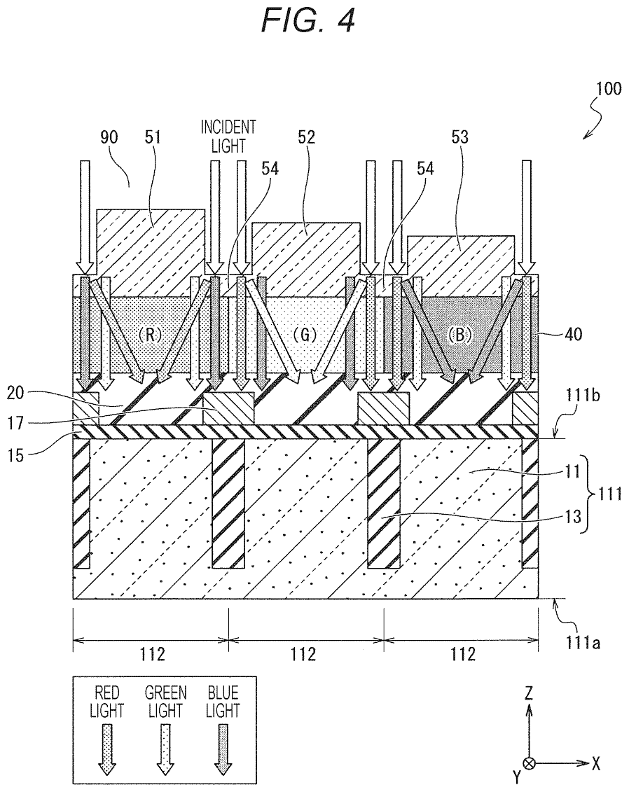

FIG. 4 is a cross-sectional view illustrating wavelength selectivity of a light condensing effect by the flat lens 50 in the imaging device 100 according to the first embodiment of the present disclosure. The thickness L_{R} (see FIG. 3) of the first lens portion 51 satisfies Equation (1). As a result, as illustrated in FIG. 4, in light propagating along a side surface of the first lens portion 51, light having the wavelength λ_{R} (that is, red light) easily reaches below the first lens portion 51, and diffraction efficiency of light having the wavelength λ_{R} is maximized. Furthermore, in light propagating along a side surface of the first lens portion 51, light (for example, light having wavelengths λ_{G} and λ_{B}) having a wavelength other than the wavelength λ_{R} is less likely to reach below the first lens portion 51, travels directly straight, and is reflected or absorbed by the light shielding film 17. Since the light having the wavelength λ_{R} in the light propagating along the side surface of the first lens portion 51 is selectively condensed on the red filter component (R), spectral characteristics of light transmitted through the red filter component (R) are improved. As a result, it becomes possible to improve the detection sensitivity of light having the wavelength λ_{R} in the pixel 112 facing the red filter component (R).

Similarly, the thickness L_{G} (see FIG. 3) of the second lens portion 52 satisfies Equation (2). As a result, in light propagating along a side surface of the second lens portion 52, light having the wavelength λ_{G} (that is, green light) easily reaches below the second lens portion 52, and diffraction efficiency of light having the wavelength λ_{G} is maximized. Furthermore, in light propagating along a side surface of the second lens portion 52, light (for example, light having wavelengths λ_{R} and λ_{B}) having a wavelength other than the wavelength λ_{G} is less likely to reach below the second lens portion 52, travels directly straight, and is reflected or absorbed by the light shielding film 17. In light propagating along a side surface of the second lens portion 52, light having the wavelength λ_{G} is selectively condensed on the green filter component (G), so that spectral characteristics of light transmitted through the green filter component (G) are improved. As a result, it becomes possible to improve the detection sensitivity of the light having the wavelength λ_{G} in the pixel 112 facing the green filter component (G).

The thickness L_{G} (see FIG. 3) of the third lens portion 53 satisfies Equation (3). As a result, in light propagating along a side surface of the third lens portion 53, light having the wavelength λ_{B} (that is, blue light) easily reaches below the third lens portion 53, and diffraction efficiency of the light having the wavelength λ_{B} is maximized. Furthermore, in light propagating along a side surface of the third lens portion 53, light (for example, light having wavelengths λ_{G} and λ_{R}) having a wavelength other than the wavelength λ_{B} is less likely to reach below the third lens portion 53, travels directly straight, and is reflected or absorbed by the light shielding film 17. Since the light having the wavelength λ_{B} in the light propagating along the side surface of the third lens portion 53 is selectively condensed on the blue filter component (B), spectral characteristics of light transmitted through the blue filter component (B) are improved. As a result, it becomes possible to improve the detection sensitivity of the light having the wavelength λ_{B} in the pixel 112 facing the blue filter component (B).

### Interval Between Lens Portions

As illustrated in FIG. 3, when an interval between the first lens portion 51 and the second lens portion 52 is set as a first interval W_{RG}, and an interval between the second lens portion 52 and the third lens portion 53 is set as a second interval W_{GB}, the first interval W_{RG} and the second interval W_{GB} may be different from each other in size. Furthermore, although not illustrated, in each embodiment of the present disclosure, the blue filter component (B) and the red filter component (R) of the color filter 40 may be adjacent to each other in the horizontal direction, and the third lens portion 53 and the first lens portion 51 may be adjacent to each other in the horizontal direction. In this case, when an interval between the third lens portion 53 and the first lens portion 51 is a third interval W_{BR}, the first interval W_{RG}, the second interval GB, and the third interval BR may be different in size from each other.

The first interval W_{RG} is expressed by the following Equation (4). The second interval GB is expressed by the following Equation (5). The third interval W_{BR} is expressed by the following Equation (6).

$$[ Mathematical Equation 2 ]$$

$$\frac{{λ}_{R} + {λ}_{G}}{4 ( {n}_{0} )} ≦ {W}_{R G} ≦ \frac{{λ}_{R} + {λ}_{G}}{{n}_{0}} \qquad ( 4 )$$

$$\frac{{λ}_{G} + {λ}_{B}}{4 ( {n}_{0} )} ≦ {W}_{G B} ≦ \frac{{λ}_{G} + {λ}_{B}}{{n}_{0}} \qquad ( 5 )$$

$$\frac{{λ}_{B} + {λ}_{R}}{4 ( {n}_{0} )} ≦ {W}_{BR} ≦ \frac{{λ}_{B} + {λ}_{R}}{{n}_{0}} \qquad ( 6 )$$

As described above, since λ_{R} is 400 nm or more and 480 nm or less and λ_{G} is 500 nm or more and 580 nm or less, λ_{R}+λ_{G} is 900 nm or more and 1060 nm or less. Since n₀=1 is satisfied in a case where the medium layer is air, the first interval W_{RG} is 225 nm or more and 1060 nm or less when calculated from Equation (4).

When the first interval W_{RG} is a value equal to or larger than a lower limit value of Equation (4), light easily enters between the first lens portion 51 and the second lens portion 52. Furthermore, when the first interval W_{RG} is a value equal to or less than an upper limit value of Equation (4), it is possible to prevent the first interval W_{RG} between the first lens portion 51 and the second lens portion 52 from becoming wider than necessary, and it is possible to suppress the presence of the first interval W_{RG} from hindering miniaturization of the pixel region 113 (see FIG. 1).

Similarly, since λ_{G} is 500 nm or more and 580 nm or less and λ_{B} is 580 nm or more and 630 nm or less, λ_{G}+λ_{B} is 1080 nm or more and 1230 nm or less. Since n₀=1 is satisfied in a case where the medium layer is air, the second interval W_{GB} is 270 nm or more and 1230 nm or less when calculated from Equation (5).

When the second interval W_{GB} is a value equal to or larger than a lower limit value of Equation (5), light easily enters between the second lens portion 52 and the third lens portion 53. Furthermore, when the second interval W_{GB} is a value equal to or less than an upper limit value of Equation (5), it is possible to prevent the second interval W_{GB} between the second lens portion 52 and the third lens portion 53 from becoming wider than necessary, and it is possible to suppress the presence of the second interval W_{GB} from hindering miniaturization of the pixel region 113.

Since λ_{B} is 580 nm or more and 630 nm or less and λ_{R} is 400 nm or more and 480 nm or less, λ_{B}+λ_{R} is 980 nm or more and 1110 nm or less. Since n₀=1 is satisfied in a case where the medium layer is air, the third interval W_{BR} is 245 nm or more and 1110 nm or less when calculated from Equation (6). When the third interval W_{BR} satisfies Equation (6), light easily enters between the second lens portion 52 and the third lens portion 53, and it is possible to suppress the presence of the third interval W_{BR} from hindering miniaturization of the pixel region 113.

### Manufacturing Method

Next, a manufacturing method for the flat lens 50 according to the first embodiment of the present disclosure will be described. The flat lens 50 is manufactured using various devices such as a resist coating device, an exposure device, and an etching device. Hereinafter, these devices are collectively referred to as a manufacturing device. The flat lens 50 can be manufactured by a manufacturing method described below.

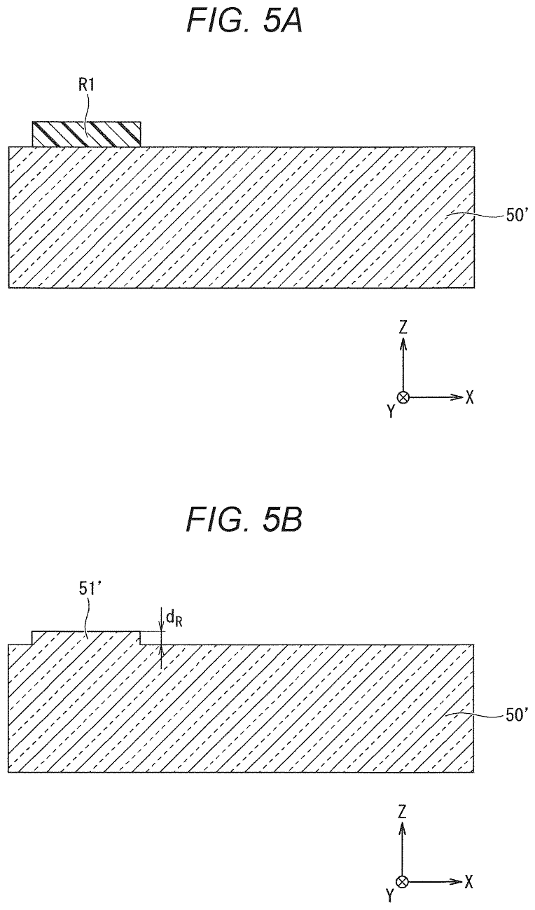

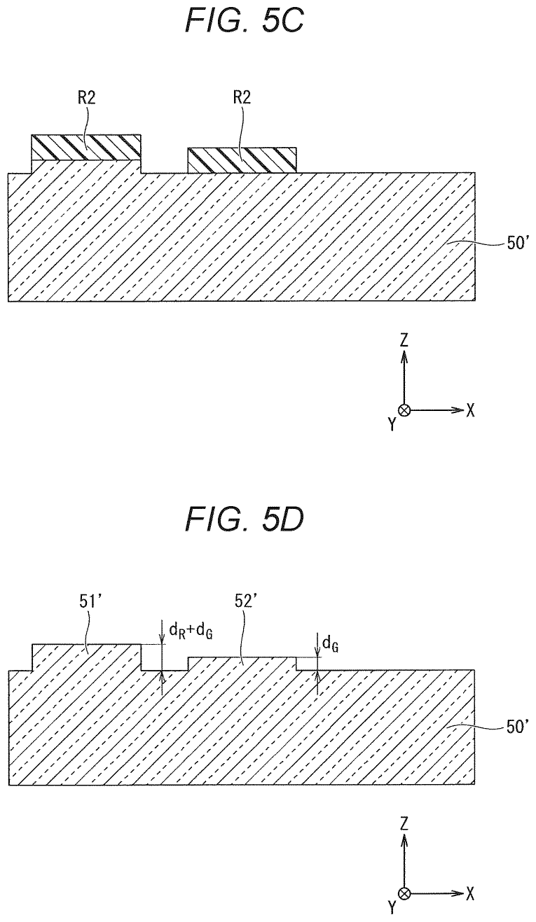

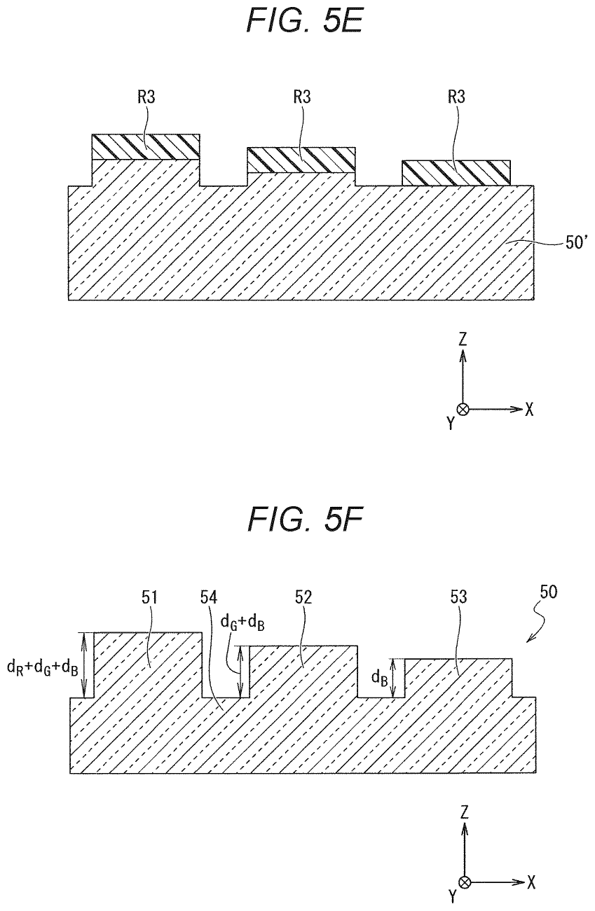

FIGS. 5A to 5F are cross-sectional views illustrating the manufacturing method for the flat lens 50 according to the first embodiment of the present disclosure in order of processes. As illustrated in FIG. 5A, the manufacturing device forms a first resist pattern R1 on one surface (in FIGS. 5A to 5F, an upper surface) of a base material 50′. The base material 50′ contains, for example, a translucent organic material or a translucent inorganic material capable of transmitting visible light. The first resist pattern R1 has a shape that covers a region where the first lens portion 51 (see FIG. 3) is formed and exposes other regions. Next, the manufacturing device performs dry etching on the one surface of the base material 50′ by using the first resist pattern R1 as a mask. As a result, as illustrated in FIG. 5B, a step having a height d_{R} is formed around a region 51′ where the first lens portion 51 is formed. Thereafter, the manufacturing device removes the first resist pattern R1.

Next, as illustrated in FIG. 5C, the manufacturing device forms a second resist pattern R2 on the one surface of the base material 50′. The second resist pattern R2 has a shape that covers a region where the first lens portion 51 is formed and a region where the second lens portion 52 (see FIG. 3) is formed, and exposes other regions. Next, the manufacturing device performs dry etching on the one surface of the base material 50′ by using the second resist pattern R2 as a mask. As a result, as illustrated in FIG. 5D, a step having a height d_{R}+d_{G} is formed around the region 51′ where the first lens portion 51 is formed, and a step having a height d_{G} is formed around a region 52′ where the second lens portion 52 is formed. Thereafter, the manufacturing device removes the second resist pattern R2.

Next, as illustrated in FIG. 5E, the manufacturing device forms a third resist pattern R3 on the one surface of the base material 50′. The third resist pattern R3 has a shape that covers a region where the first lens portion 51 is formed, a region where the second lens portion 52 is formed, and a region where the third lens portion 53 is formed, and exposes other regions. Next, the manufacturing device performs dry etching on the one surface of the base material 50′ by using the third resist pattern R3 as a mask. As a result, as illustrated in FIG. 5F, the first lens portion 51, the second lens portion 52, and the third lens portion 53 are formed. A step having a height d_{R}+d_{G}+d_{B} is formed around the first lens portion 51, a step having a height d_{G}+d_{B} is formed around the second lens portion 52, and a step having a height d_{B} is formed around the third lens portion 53. Thereafter, the manufacturing device removes the third resist pattern R3.

The flat lens 50 is completed according to the above processes. The height d_{R}+d_{G}+d_{B} illustrated in FIG. 5F corresponds to the thickness L_{R} (see FIG. 3) of the first lens portion 51. The height d_{G}+d_{B} illustrated in FIG. 5F corresponds to the thickness L_{G} (see FIG. 3) of the second lens portion 52. The height d_{B} illustrated in FIG. 5F corresponds to the thickness L_{B} (see FIG. 3) of the third lens portion 53.

### Effect of First Embodiment

As described above, the imaging device 100 according to the first embodiment of the present disclosure includes: the substrate 111 on which a plurality of pixels is arranged; the color filter 40 provided on the back surface 111b side of the substrate 111; and the flat lens 50 having a flat light incident surface and provided on the back surface 111b side of the substrate 111 with the color filter 40 interposed in between. The thickness of the flat lens 50 is mutually different between the adjacent pixels 112. For example, the color filter 40 includes the red filter component (R) that transmits red light, the green filter component (G) that transmits green light, and the blue filter component (B) that transmits blue light. The flat lens 50 includes the first lens portion 51 facing the red filter component (R), the second lens portion 52 facing the green filter component (G), and the third lens portion 53 facing the blue filter component (B). The first lens portion 51, the second lens portion 52, and the third lens portion 53 have mutually different thicknesses.

According to this configuration, the thickness of the first lens portion 51 can be designed such that diffraction efficiency of red light is maximized. As a result, red light can be condensed on the pixel 112 (hereinafter, also referred to as a pixel for red color detection) facing the first lens portion 51 with the red filter component (R) interposed in between, and other light can be made difficult to be condensed. Similarly, the thickness of the second lens portion 52 can be designed such that the diffraction efficiency of green light is maximized. As a result, green light can be condensed on the pixel 112 (hereinafter, also referred to as a pixel for green color detection) facing the second lens portion 52 with the green filter component (G) interposed in between, and other light can be made difficult to be condensed. The thickness of the third lens portion 53 can be designed such that the diffraction efficiency of blue light is maximized. As a result, blue light can be condensed on the pixel 112 (hereinafter, also referred to as a pixel for blue color detection) facing the third lens portion 53 with the blue filter component (B) interposed in between, and other light can be made difficult to be condensed.

For the light condensing effect on the pixels 112 by the flat lens 50, wavelength selectivity can be imparted to each pixel for red color detection, each pixel for green color detection, and each pixel for blue color detection. As a result, spectral characteristics of light incident on each pixel 112 can be improved. It is possible to suppress color mixing of light incident on each pixel 112.

### Second Embodiment

In the first embodiment described above, it has been described that the medium layer located on the side opposite to the color filter 40 with the flat lens 50 interposed in between is air. However, the embodiment of the present disclosure is not limited thereto. The medium layer may be a layer other than air.

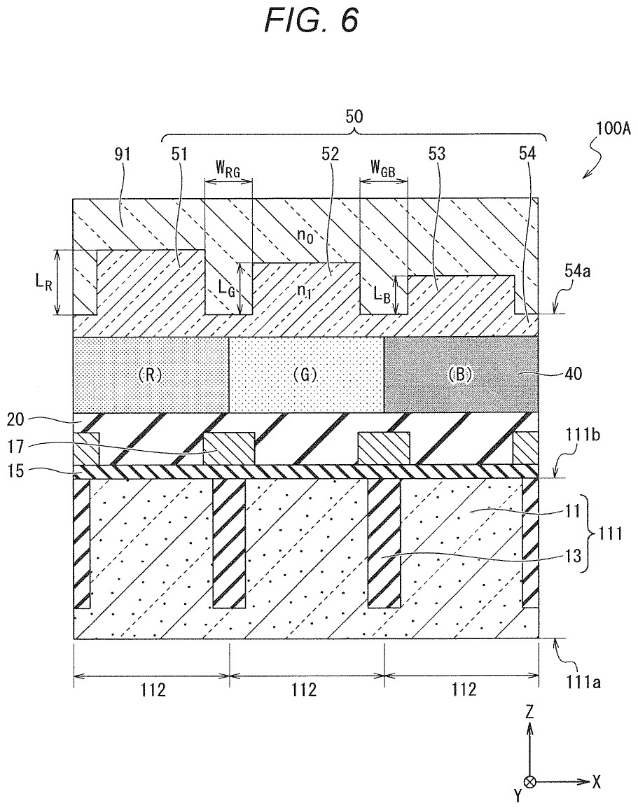

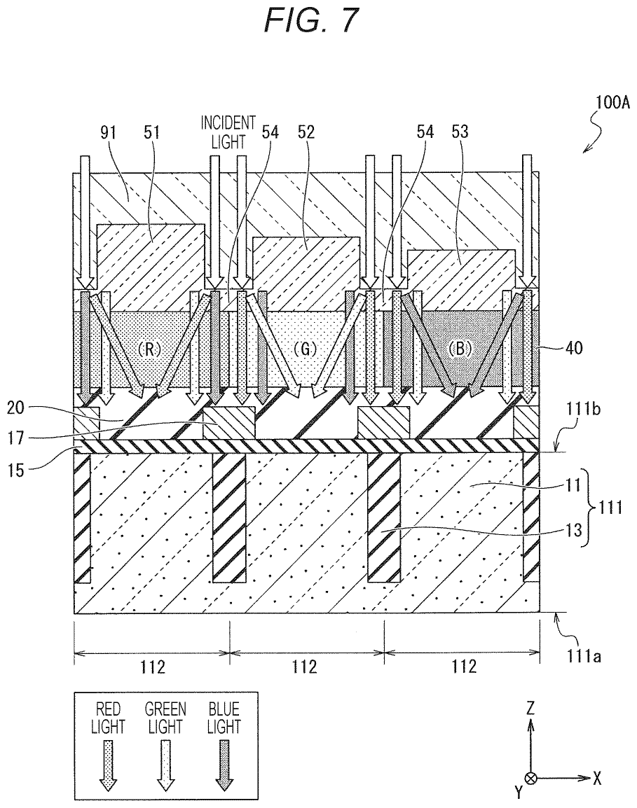

FIG. 6 is a cross-sectional view illustrating a configuration example of an imaging device 100A according to a second embodiment of the present disclosure. FIG. 7 is a cross-sectional view illustrating wavelength selectivity of a light condensing effect by a flat lens 50 in the imaging device 100A according to the second embodiment of the present disclosure.

As illustrated in FIG. 6, the imaging device 100A includes a protective layer 91 provided on the flat lens 50 as an example of a medium layer. The protective layer 91 is, for example, a silicon oxide film (SiO₂ film) or a silicon nitride film (SiN film). In a case where the protective layer 91 is a SiO₂ film, n₀ is 1.45. In a case where the protective layer 91 is a SiN film, n₀ is 2.1.

In the second embodiment, a thickness L_{R} (see FIG. 6) of a first lens portion 51 of the flat lens 50 satisfies Equation (1) described above. A thickness L_{G} (see FIG. 6) of a second lens portion 52 satisfies Equation (2) described above. A thickness L_{B} (see FIG. 6) of a third lens portion 53 satisfies Equation (3) described above. As a result, similarly to the first embodiment described above, as illustrated in FIG. 7, wavelength selectivity can be imparted to a light condensing effect of the flat lens 50, and spectral characteristics of light incident on each pixel 112 can be improved. It is possible to suppress color mixing of light incident on each pixel 112.

Furthermore, also in the second embodiment, a first interval W_{RG} between the first lens portion 51 and the second lens portion 52 preferably satisfies Equation (4). A second interval W_{GB} between the second lens portion 52 and the third lens portion 53 preferably satisfies Equation (5). In a case where the third lens portion 53 and the first lens portion 51 are adjacent to each other, a third interval W_{BR} between the third lens portion 53 and the first lens portion 51 preferably satisfies Equation (6). As a result, similarly to the first embodiment described above, light easily enters between adjacent lens portions, and it is possible to prevent an interval between the adjacent lens portions from hindering miniaturization of a pixel region 113 (see FIG. 1).

### Third Embodiment

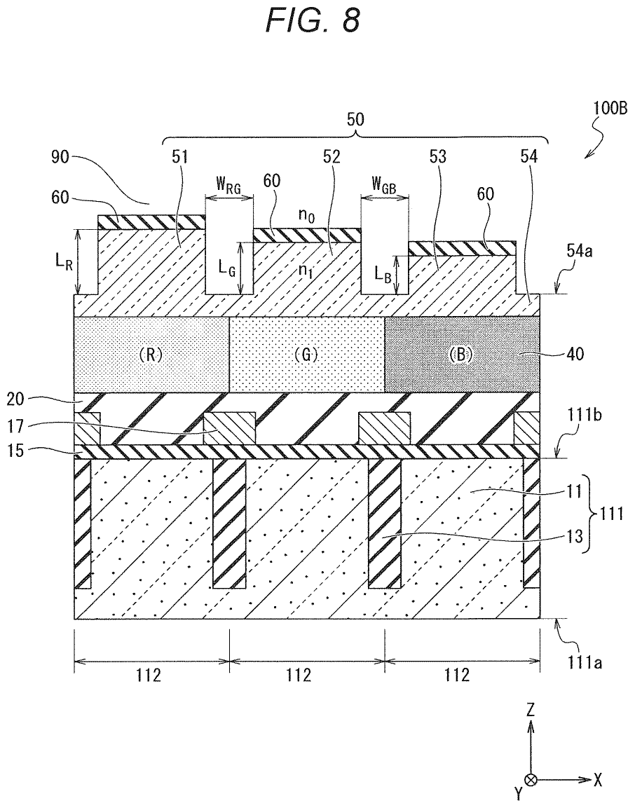

FIG. 8 is a cross-sectional view illustrating a configuration example of an imaging device 100B according to a third embodiment of the present disclosure. As illustrated in FIG. 8, the imaging device 100B includes an antireflection film 60 on a flat lens 50. For example, the antireflection film 60 is provided on each of a first lens portion 51, a second lens portion 52, and a third lens portion 53.

Also in the third embodiment, a thickness L_{R} of the first lens portion 51, a thickness L_{G} of the second lens portion 52, and a thickness L_{B} of the third lens portion 53 satisfy Equations (1), (2), and (3) described above, respectively. As a result, similarly to the first embodiment described above, wavelength selectivity can be imparted to a light condensing effect of the flat lens 50. Spectral characteristics of light incident on each pixel 112 can be improved, and color mixing of light incident on each pixel 112 can be suppressed.

Furthermore, also in the third embodiment, a first interval W_{RG} and a second interval W_{GB} preferably satisfy Equations (4) and (5). In a case where the third lens portion 53 and the first lens portion 51 are adjacent to each other, a third interval W_{BR} preferably satisfies Equation (6). As a result, similarly to the first embodiment described above, light easily enters between adjacent lens portions, and it is possible to prevent an interval between the adjacent lens portions from hindering miniaturization of a pixel region 113 (see FIG. 1).

Note that, as illustrated in FIG. 8, a medium layer may be air 90 or a protective layer 91 (see FIG. 6). In a case where the medium layer is the air 90, n₀=1 is satisfied in Equations (1) to (6) described above. In a case where the medium layer is the protective layer 91, n₀ is a refractive index of a material contained in the protective layer 91. For example, n₀=1.45 is satisfied in a case where the protective layer 91 is a SiO₂ film, and n₀=2.1 is satisfied in a case where the protective layer 91 is a SiN film.

### Fourth Embodiment

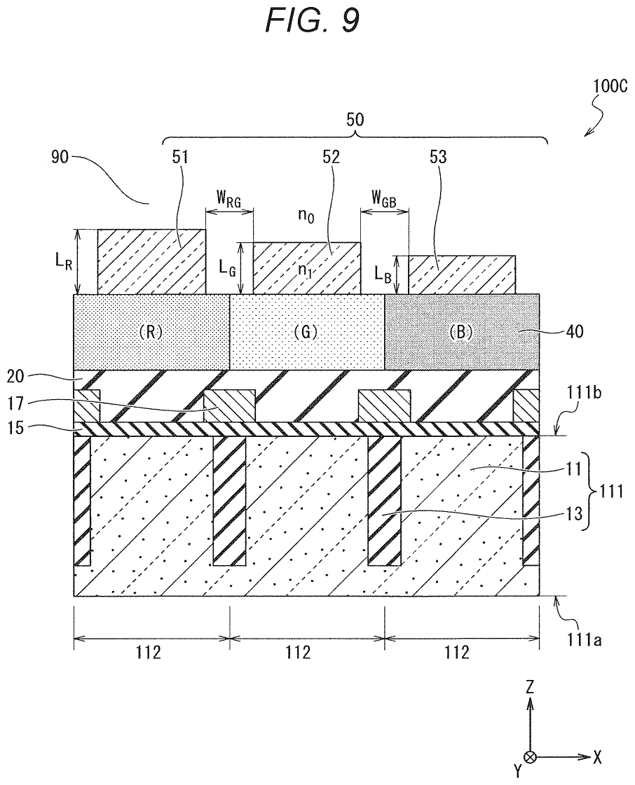

FIG. 9 is a cross-sectional view illustrating a configuration example of an imaging device 100C according to a fourth embodiment of the present disclosure. As illustrated in FIG. 9, in the fourth embodiment, a base part 54 (see FIG. 3) is not present in a flat lens 50. A first lens portion 51, a second lens portion 52, and a third lens portion 53 are arranged on a color filter 40 directly or with a translucent thin film (not illustrated) interposed in between. The first lens portion 51, the second lens portion 52, and the third lens portion 53 are formed using, for example, a printing technique.

Also in the fourth embodiment, a thickness L_{R} of the first lens portion 51, a thickness L_{G} of the second lens portion 52, and a thickness L_{B} of the third lens portion 53 satisfy Equations (1), (2), and (3) described above, respectively. As a result, similarly to the first embodiment described above, wavelength selectivity can be imparted to a light condensing effect of the flat lens 50. Spectral characteristics of light incident on each pixel 112 can be improved, and color mixing of light incident on each pixel 112 can be suppressed.

Furthermore, also in the fourth embodiment, a first interval W_{RG} and a second interval W_{GB} preferably satisfy Equations (4) and (5). In a case where the third lens portion 53 and the first lens portion 51 are adjacent to each other, a third interval W_{BR} preferably satisfies Equation (6). As a result, similarly to the first embodiment described above, light easily enters between adjacent lens portions, and it is possible to prevent an interval between the adjacent lens portions from hindering miniaturization of a pixel region 113 (see FIG. 1).

### Fifth Embodiment

In the first embodiment described above, the case where the first lens portion 51, the second lens portion 52, and the third lens portion 53 each have a rectangular shape in plan view has been described. However, the embodiment of the present disclosure is not limited thereto.

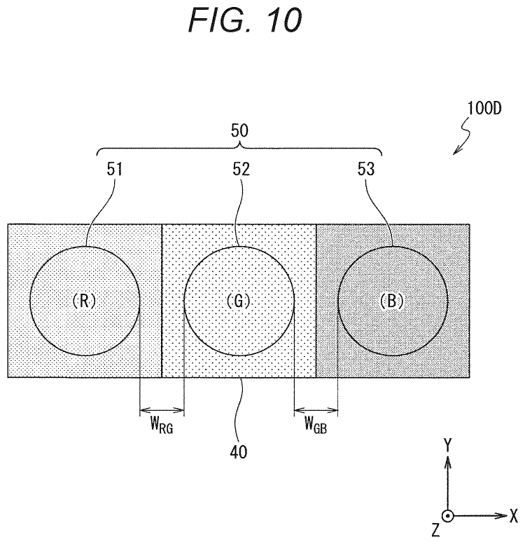

FIG. 10 is a plan view illustrating a configuration example of a color filter 40 and a flat lens 50 of an imaging device 100D according to a fifth embodiment of the present disclosure. As illustrated in FIG. 10, shapes of a first lens portion 51, a second lens portion 52, and a third lens portion 53 in plan view may be circular. Furthermore, although not illustrated, the shape of the first lens portion 51, the second lens portion 52, and the third lens portion 53 in plan view may be a polygon other than a rectangle, such as a hexagon or an octagon.

Also in the fifth embodiment, since a thickness L_{R} of the first lens portion 51, a thickness L_{G} of the second lens portion 52, and a thickness L_{B} of the third lens portion 53 satisfy Equations (1), (2), and (3) described above, respectively, wavelength selectivity can be imparted to a light condensing effect of the flat lens 50. Spectral characteristics can be improved, and color mixing of light incident on each pixel 112 can be suppressed.

### Sixth Embodiment

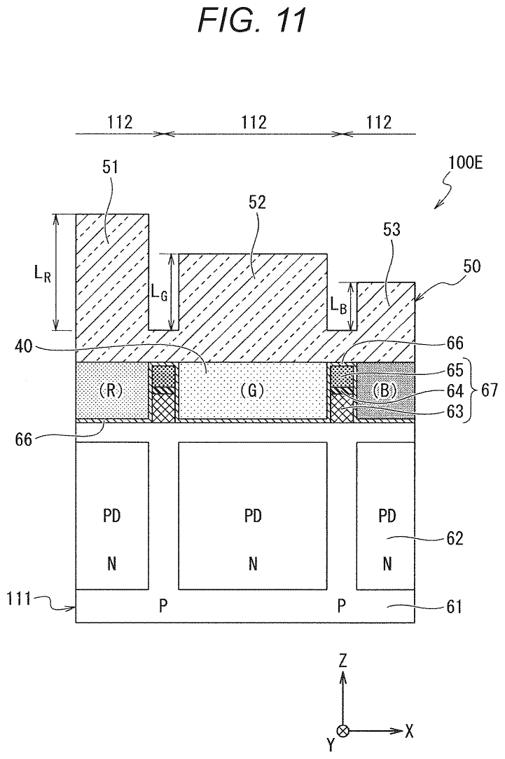

FIG. 11 is a cross-sectional view illustrating a configuration example of an imaging device 100E according to a sixth embodiment of the present disclosure. A substrate 111 illustrated in FIG. 11 contains, for example, silicon (Si), and has a thickness of, for example, 1 μm or more and 6 μm or less. In the substrate 111, for example, an N-type (second conductivity type) semiconductor region 62 is formed for every pixel 112 in a P-type (first conductivity type) semiconductor region 61, so that a photodiode PD is formed for each pixel.

The upper side of FIG. 11 is a back surface side of the substrate 111 on which light enters, and the lower side of FIG. 11 is a front surface side of the substrate 111 on which pixel transistors and multilayer wiring layers (not illustrated) are formed. Therefore, the imaging device 100E adopting the pixel structure of FIG. 11 is a back-illuminated CMOS image sensor in which light enters from the back surface side of the substrate 111.

In the figure, on the back surface side of the substrate, which is an upper side of the substrate 111, a light shielding film 63 to prevent leakage of incident light to an adjacent pixel is formed at a boundary portion between adjacent pixels 112, and a first low refractive index film 64 and a second low refractive index film 65 having a refractive index lower than that of the light shielding film 63 are laminated on the light shielding film 63.

A material contained in the light shielding film 63 may be any material as long as light is shielded, and for example, a metal film of tungsten (W), aluminum (Al), copper (Cu), or the like or an oxide film thereof can be used. Furthermore, a material contained in the light shielding film 63 may be an organic resin material in which a carbon black pigment or a titanium black pigment is internally added.

Moreover, the light shielding film 63 may have a laminated structure of a plurality of metal films in which, for example, tungsten (W) formed with a film thickness of about 200 nm is used as a lower layer and titanium (Ti) formed with a film thickness of about 30 nm is used as an upper layer.

The first low refractive index film 64 and the second low refractive index film 65 can include, for example, an inorganic film such as SiN, SiO₂, or SiON, or a resin material (organic film) such as a styrene resin, an acrylic resin, a styrene-acrylic copolymer resin, or a siloxane resin.

In the sixth embodiment of the present disclosure, the first low refractive index film 64 contains SiN formed with a film thickness of, for example, about 50 nm, and the second low refractive index film 65 contains SiO₂ formed with a film thickness of, for example, about 550 nm.

Note that, in the following description, three layers of the light shielding film 63, the first low refractive index film 64, and the second low refractive index film 65 are collectively referred to as a first wall 67, and pixels are separated by the first wall 67 at a boundary portion between adjacent pixels. A height of the first wall 67 is appropriately set, for example, within a range of 50 nm or more and 2000 nm or less, and a width of the first wall 67 is appropriately set within a range of 50 nm or more and 300 nm or less according to a pixel size or the like.

Then, a lamination surface of the first wall 67 and an upper surface on the back side of the substrate 111 on which the first wall 67 is not formed are covered with a protective film 66 such as a Si oxide film. The protective film 66 is a film for prevention of corrosion, and can be formed with a film thickness of, for example, about 50 nm or more and 150 nm or less, but is not necessarily formed.

A color filter 40 of any of red (R), green (G), and blue (B) is formed above the photodiode PD on the back surface side of the substrate 111 with the protective film 66 interposed in between. A height (film thickness) of the color filter 40 and a height of the first wall 67 are made to be the same. In a case where the protective film 66 is formed, a total height of the protective film 66 and the first wall 67 is the same as the height of the color filter 40.

A first lens portion 51, a second lens portion 52, or a third lens portion 53 of a flat lens 50 is formed for every pixel 112 on the upper side of the layers of the first wall 67 and the color filter 40. The flat lens 50 is formed using, for example, a resin material such as a styrene resin, an acrylic resin, a styrene-acrylic copolymer resin, or a siloxane resin. Incident light is condensed by the flat lens 50, and the condensed light efficiently enters the photodiode PD through the color filter 40 interposed. Note that an antireflection film may be formed on a surface layer of the flat lens 50.

Among the light shielding film 63, the first low refractive index film 64, and the second low refractive index film 65, the second low refractive index film 65 closest to the flat lens 50 is a film having the lowest refractive index, and the refractive index sequentially increases toward the first low refractive index film 64, the light shielding film 63, and the substrate 111 side.

Specifically, in a case where the second low refractive index film 65 contains SiO₂, the first low refractive index film 64 contains SiN, and the light shielding film 63 contains a two-layer structure of titanium/tungsten (Ti/W), the refractive index of the second low refractive index film 65 is about 1.5, the refractive index of the first low refractive index film 64 is about 1.7, and the refractive index of the light shielding film 63 is about 2.7.

Note that the refractive indexes of the first low refractive index film 64 and the second low refractive index film 65 are appropriately set within a range of, for example, about 1.00 to 1.70 according to a pixel size or the like.

The refractive index of the flat lens 50 can be appropriately set within a range of 1.50 or more and 2.0 or less, and is, for example, about 1.55 or more and 1.60 or less.

In this manner, by laminating the low refractive index film (the first low refractive index film 64 and the second low refractive index film 65) having a refractive index lower than that of the light shielding film 63 formed at a boundary of individual pixels 112 two-dimensionally arranged, it is possible to improve sensitivity while suppressing color mixing.

Also in the sixth embodiment, a thickness L_{R} of the first lens portion 51, a thickness L_{G} of the second lens portion 52, and a thickness L_{B} of the third lens portion 53 satisfy Equations (1), (2), and (3) described above, respectively. As a result, similarly to the first embodiment described above, wavelength selectivity can be imparted to a light condensing effect of the flat lens 50. Spectral characteristics of light incident on each pixel 112 can be improved, and color mixing of light incident on each pixel 112 can be suppressed.

Furthermore, also in the sixth embodiment, a first interval W_{RG} and a second interval W_{GB} preferably satisfy Equations (4) and (5). In a case where the third lens portion 53 and the first lens portion 51 are adjacent to each other, a third interval W_{BR} preferably satisfies Equation (6). As a result, similarly to the first embodiment described above, light easily enters between adjacent lens portions, and it is possible to prevent an interval between the adjacent lens portions from hindering miniaturization of a pixel region 113 (see FIG. 1).

### Other Embodiments

As described above, the present disclosure has been described according to the embodiments and modifications, but it should not be understood that the description and drawings forming a part of this disclosure limit the present disclosure. Various alternative embodiments, examples, and operation techniques will be apparent to those skilled in the art from this disclosure. It is a matter of course that the present technology includes various embodiments and the like not described herein. At least one of various omissions, substitutions, or changes of the components may be made without departing from the gist of the above-described embodiments and variations. Furthermore, the effect described in the present description is illustrative only; the effect is not limited thereto and there may also be another effect.

Note that the present disclosure can also have the following configurations.

### (1)

An imaging device including:
a semiconductor layer in which a plurality of pixels is arranged;
a color filter provided on one surface side of the semiconductor layer; and
a flat lens having a flat light incident surface and provided on the one surface side of the semiconductor layer with the color filter interposed in between, in which
a thickness of the flat lens is mutually different between adjacent pixels.

### (2)

An imaging device including:
a semiconductor layer in which a plurality of pixels is arranged;
a color filter provided on one surface side of the semiconductor layer; and
a flat lens having a flat light incident surface and provided on the one surface side of the semiconductor layer with the color filter interposed in between, in which
the color filter includes:
a first filter component that transmits light of a first color; and
a second filter component that transmits light of a second color different from the first color,
the flat lens includes:
a first lens portion facing the first filter component; and
a second lens portion facing the second filter component, and
the first lens portion and the second lens portion have mutually different thicknesses.

### (3)

The imaging device according to (2), in which
the color filter further includes:
a third filter component that transmits light of a third color different from the first color and the second color,
the flat lens further includes:
a third lens portion facing the third filter component, and
the first lens portion, the second lens portion, and the third lens portion have mutually different thicknesses.

### (4)

The imaging device according to (3), in which each of the first lens portion, the second lens portion, and the third lens portion has a rectangular cross-sectional shape taken along a plane orthogonal to the incident surface.

### (5)

The imaging device according to (3) or (4), in which each of the first lens portion, the second lens portion, and the third lens portion has a rectangular shape in plan view from a direction orthogonal to the incident surface.

### (6)

The imaging device according to any one of (3) to (5), in which
the first color is red,
the second color is green,
the third color is blue,
a thickness of the first lens portion is 181 nm or more and 800 nm or less,
a thickness of the second lens portion is 227 nm or more and 967 nm or less, and
a thickness of the third lens portion is 263 nm or more and 1084 nm or less.

### (7)

The imaging device according to any one of (3) to (6), in which
when an interval between the first lens portion and the second lens portion is set as a first interval, and
an interval between the second lens portion and the third lens portion is set as a second interval,
the first interval and the second interval have mutually different sizes.

### (8)

The imaging device according to (7), in which
the first color is red,
the second color is green,
the third color is blue,
the first interval is 225 nm or more and 1060 nm or less, and
the second interval is 270 nm or more and 1230 nm or less.

### (9)

The imaging device according to any one of (1) to (8), in which
a refractive index of the flat lens is
a value higher than a refractive index of a medium layer located on a side opposite to the color filter with the flat lens interposed in between.

### Reference Signs List

11 Photoelectric conversion element

13 Element isolation layer

15, 20 Insulating film

17, 63 Light shielding film

40 Color filter

50 Flat lens

50′ Base material

51 First lens portion

52 Second lens portion

53 Third lens portion

54 Base part

54a Upper surface

60 Antireflection film

61, 62 Semiconductor region

64 First low refractive index film

65 Second low refractive index film

66 Protective film

67 First wall

90 Air

91 Protective layer

100, 100A, 100B, 100C, 100D, 100E IMAGING DEVICE

111 Substrate

111a Front surface

111b Back surface

112 Pixel

113 Pixel region

114 Vertical drive circuit

115 Column signal processing circuit

116 Horizontal drive circuit

117 Output circuit

118 Control circuit

119 Vertical signal line

120 Horizontal signal line

B Blue filter component

G Green filter component

PD Photodiode

R Red filter component

R1 First resist pattern

R2 Second resist pattern

R3 Third resist pattern

1. An imaging device comprising:
a semiconductor layer in which a plurality of pixels is arranged;
a color filter provided on one surface side of the semiconductor layer; and
a flat lens having a flat light incident surface and provided on the one surface side of the semiconductor layer with the color filter interposed in between, wherein
a thickness of the flat lens is mutually different between adjacent pixels.

2. An imaging device comprising:
a semiconductor layer in which a plurality of pixels is arranged;
a color filter provided on one surface side of the semiconductor layer; and
a flat lens having a flat light incident surface and provided on the one surface side of the semiconductor layer with the color filter interposed in between, wherein
the color filter includes:
a first filter component that transmits light of a first color; and
a second filter component that transmits light of a second color different from the first color,
the flat lens includes:
a first lens portion facing the first filter component; and
a second lens portion facing the second filter component, and
the first lens portion and the second lens portion have mutually different thicknesses.

3. The imaging device according to claim 2, wherein
the color filter further includes:
a third filter component that transmits light of a third color different from the first color and the second color,
the flat lens further includes:
a third lens portion facing the third filter component, and
the first lens portion, the second lens portion, and the third lens portion have mutually different thicknesses.

4. The imaging device according to claim 3, wherein each of the first lens portion, the second lens portion, and the third lens portion has a rectangular cross-sectional shape taken along a plane orthogonal to the incident surface.

5. The imaging device according to claim 3, wherein each of the first lens portion, the second lens portion, and the third lens portion has a rectangular shape in plan view from a direction orthogonal to the incident surface.

6. The imaging device according to claim 3, wherein
the first color is red,
the second color is green,
the third color is blue,
a thickness of the first lens portion is 181 nm or more and 800 nm or less,
a thickness of the second lens portion is 227 nm or more and 967 nm or less, and
a thickness of the third lens portion is 263 nm or more and 1084 nm or less.

7. The imaging device according to claim 3, wherein
when an interval between the first lens portion and the second lens portion is set as a first interval, and
an interval between the second lens portion and the third lens portion is set as a second interval,
the first interval and the second interval have mutually different sizes.

8. The imaging device according to claim 7, wherein
the first color is red,
the second color is green,
the third color is blue,
the first interval is 225 nm or more and 1060 nm or less, and
the second interval is 270 nm or more and 1230 nm or less.

9. The imaging device according to claim 1, wherein
a refractive index of the flat lens is
a value higher than a refractive index of a medium layer located on a side opposite to the color filter with the flat lens interposed in between.
